(19) United States
(12) Patent Application Publication
(10) Pub. No.: US 2006/0281321 A1
(43) Pub. Date: Dec. 14, 2006

(54) Nanowire sensor device structures

(76) Inventors: John F. Conley JR., Camas, WA (US); Yoshi Ono, Camas, WA (US); Lisa H. Stecker, Vancouver, WA (US)

Correspondence Address: SHARP LABORATORIES OF AMERICA, INC, 5750 NW PACIFIC RIM BLVD, CAMAS, WA, 98642, US

(21) Appl. No.: 11/152,289

(22) Filed: Jun. 13, 2005

(51) Int. Cl. H01L 21/311

(52) U.S. Cl. 438/703

(57) ABSTRACT

A method of fabricating a nanowire sensor device structure includes preparing a substrate, having a silicon base layer, a buried oxide layer in the silicon base layer, a top silicon layer on the buried oxide layer, and a doped well in the silicon base layer; forming a silicon island from the top silicon layer; etching the buried oxide layer to undercut the silicon island in some instances; depositing a seed layer of polycrystalline ZnO over the silicon island, the buried oxide layer, the doped well and the silicon base layer; selectively removing the polycrystalline ZnO from the silicon island; growing and structuring ZnO nanostructures on the seed layer of ZnO; treating the ZnO nanostructures to sensitize the ZnO nanostructures to a desired application; depositing a layer of insulating material; patterning and etching the insulating material; and metallizing the nanowire device structure.

### FIELD OF THE INVENTION

This invention relates to nanotechnology and/or microelectronics, and specifically to solid state sensors and detectors which are particularly well suited for use in optoelectronic devices.

### BACKGROUND OF THE INVENTION

There is an increasing need for inexpensive, sensitive solid state gas sensors for applications such as pollution and toxic gas monitoring, homeland security, “lab-on-a-chip”, etc. It is known that materials, such as metal oxides, exhibit sensitivity to various gases because of their ability to adsorb these gases in their surfaces. Recently, solid state gas sensors have been proposed and fabricated which employ planar thin films of these metal oxides, such as In₂O₃, SnO₂, Fe₂O₃, and ZnO, to detect and quantify various gases. Nanostructured materials, because of their inherent high surface area relative to the volume of material, have been reported to be ideal for sensing applications. However, the lack of a reasonable method to fabricate a useful, i.e., electrically measurable and MOS integratable, device using nanostructured materials, has prevented widespread use of these materials.

Martins et al., Zinc oxide as an ozone sensor, J. Appl. Phys. 96(3), 1398 (2004), describes the use of a UV bombarded ZnO film-on-glass as a sensor.

Gordillo et al., Effect of gas chemisorption on the electrical conductivity of ZnO thin films, Advances in Mat. Sci. and Tech. 1(1), 1 (1996), describes use of an annealed ZnO thin film as a detector for CO₂, O₂, H₂ and CH₄.

### SUMMARY OF THE INVENTION

A method of fabricating a nanowire sensor device structure includes preparing a substrate, having a silicon base layer, a buried oxide layer in the silicon base layer in some instances, a top silicon layer on the buried oxide layer, and a doped well in the silicon base layer; forming a silicon island from the top silicon layer; etching the buried oxide layer; etching the buried oxide layer to undercut the silicon island; depositing a seed layer of polycrystalline ZnO over the silicon island, the buried oxide layer, the doped well and the silicon base layer; removing the polycrystalline ZnO from the top of the silicon island; growing ZnO nanostructures on the seed layer of ZnO; removing ZnO and extraneous nanostructures from the edges of the silicon islands; treating the ZnO nanostructures to sensitize the ZnO nanostructures to a desired application; depositing a layer of insulating material; patterning and etching the insulating material; and metallizing the nanowire device structure.

It is an object of the invention to provide a method of fabricating a nanowire sensor device.

Another object of the method of the invention is to provide a nanowire sensor which may be fabricated using conventional, state-of-the-art IC fabrication processes.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram of the method of the invention.

FIGS. 2-9 depicts steps in fabricating a sensor device according to a first embodiment of the method of the invention.

FIGS. 10-13 depicts steps in fabricating a sensor device according to alternate embodiments of the method of the invention.

FIGS. 14 and 15 are SEM photos which demonstrate the feasibility of the method of the invention.

### DETAILED DESCRIPTION OF THE PREFERRED EMBODIMENTS

The method of the invention provides a protocol for fabricating a solid state gas sensor on a silicon-on-insulator (SOI) substrate which incorporates ZnO nanowire bridges. Selective growth of ZnO nanowire bridges is achieved using an ALD ZnO seed layer in some embodiments of the method of the invention. The method of the invention is compatible with standard microelectronic processing techniques and may be integrated with CMOS devices.

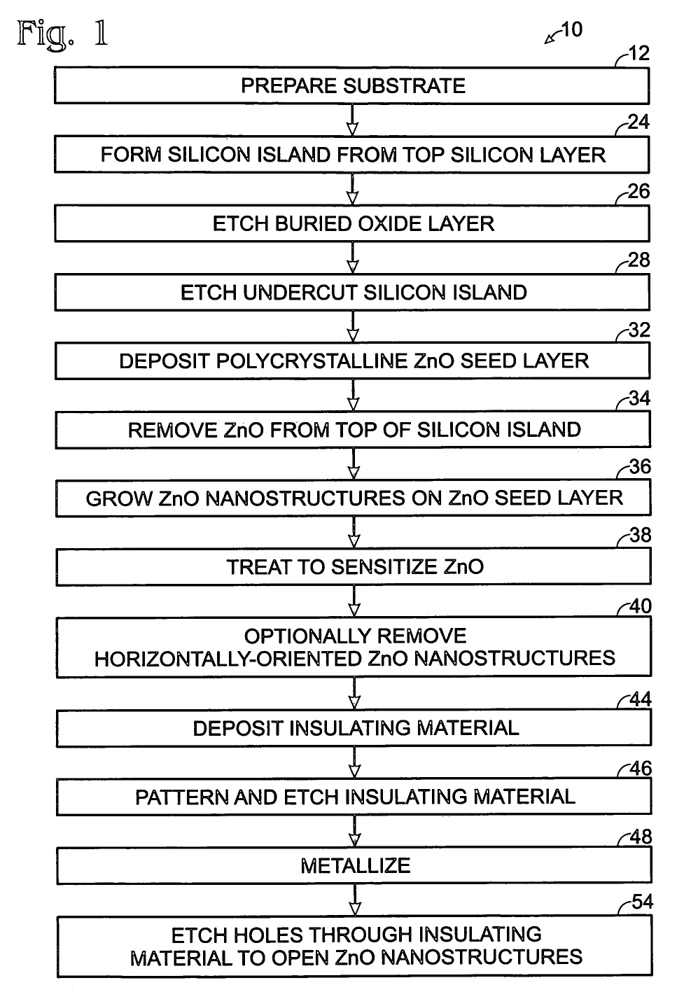

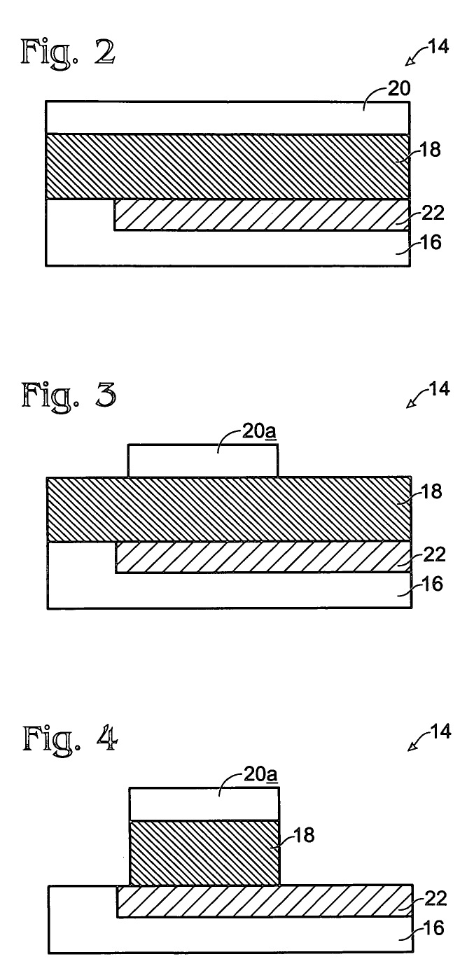

The steps of the method of the invention are shown in FIG. 1, generally at 10, which figure is to be viewed in conjunction with FIGS. 2-13. Fabrication of the sensor begins with preparation 12 of a cleaned SOI substrate 14, including a silicon wafer 16, having a buried oxide (BOX) layer 18 formed therein, and a doped single crystalline silicon overlayer 20 formed on the BOX layer. The SOI substrate may be manufactured by any standard process, however, bond-and-etchback or SmartCut™, substrates are preferred over SIMOX. Polysilicon-on-oxide on a silicon substrate may also be used. A doped well 22, which may be either n+ or p+, is formed by ion implantation to complete preparation of the substrate.

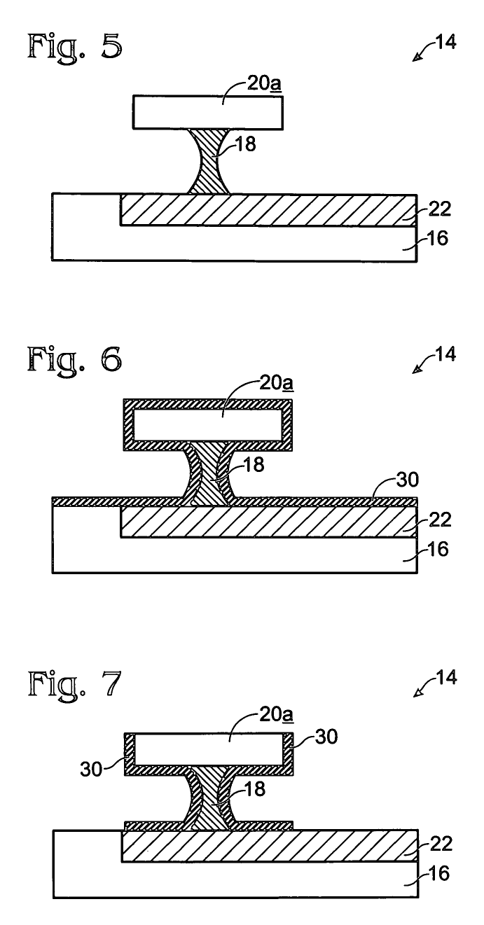

Next, silicon surface 20 is coated with photoresist, patterned, and dry etched 24 to produce a silicon island 20a that is electrically insulated from the substrate, as shown in FIG. 3. BOX layer 18 is dry etched 26 to produce the structure in FIG. 4. Dry etch 26 is followed by a wet etch 28 in HF to undercut the silicon island, as shown in FIG. 5.

A thin seed layer 30 of poly-crystalline ZnO is deposited 32 on the surface of the wafer using atomic layer deposition (ALD). It has been previously disclosed that ALD ZnO may be used as a seed layer for ZnO nanostructure growth in U.S. patent application Ser. No. 10/976,594, of Stecker et al., filed Oct. 29, 2004, for ALD ZnO Seed Layer for Deposition of ZnO nanostructures on a Si substrate, wherein a ZnO film was described as being used as a seed layer for ZnO nanostructure growth. In this implementation of the method of the invention, about 10 nm of ALD ZnO is deposited using 35 cycles of alternating pulses of a precursor, such as diethylzinc (DEZ), and H₂O vapor, at a substrate temperature of between about 130° C. to 200° C., although any thickness of ZnO from between about 1 nm to 70 nm may be used. The ALD method of deposition is necessary to conformally coat the underside of the undercut island.

The ALD ZnO surface is coated with photoresist, patterned, and dry etched to remove ZnO 34. Dry etching is used so that the thin ALD coating remains under the island. The photoresist is then stripped and a patterned ZnO surface remains as shown in FIG. 7.

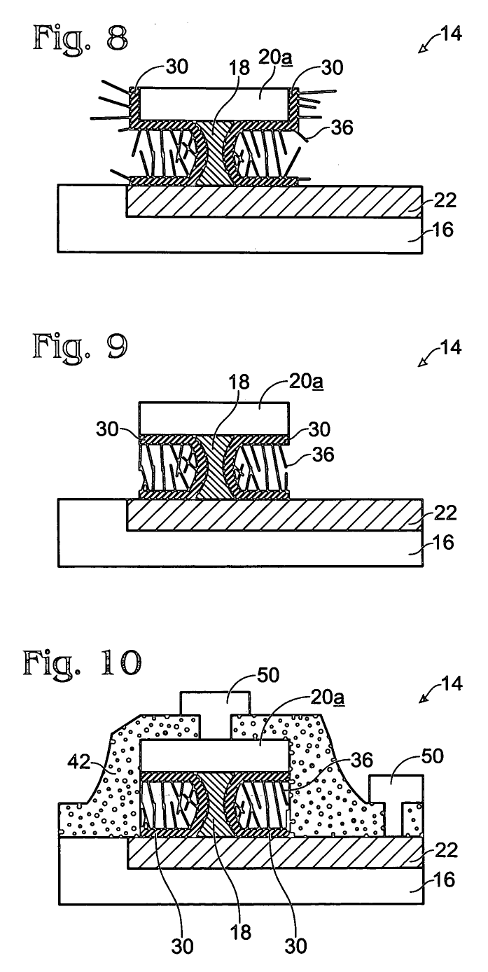

ZnO nanostructure growth is next induced. For this embodiment, the structure of FIG. 7 is exposed to Zn vapor in the presence of a trace amount of oxygen at 915° C., for about 30 minutes. Zn vapor is generated through carbo-thermal reduction of ZnO powder using equal parts ZnO and graphite. In principal, however, any method of supplying gas phase Zn for growing would work similarly. Growth takes place via a vapor-solid mechanism only on ALD ZnO seed layer 30, as previously disclosed in U.S. patent application Ser. No. 10/977,430, of Conley, Jr. et al., file Oct. 29, 2004, for Selective growth of ZnO nanowires using a patterned ALD ZnO seed layer, which describes selective growth of ZnO nanowires is achieved using a patterned ZnO seed layer. Selective, patterned growth of ZnO nanostructures 36 is observed, as illustrated in FIG. 8. Some of these nanowires will bridge the gap between the substrate and silicon island 20a. These nanowire bridges will form the sensitive part of the gas sensor. After this step, an anneal, or other treatment, may be applied to modify the surface of the ZnO nanowires to an appropriate state to flnctionalize or enhance sensitivity to a desired gas 38, or to a biological species.

To clean the edges of the structure, the horizontally oriented nanostructures and ZnO on the side(s) of silicon island 20a may be selectively removed with an optional dry etch 40, also referred to herein as structuring the nanostructures and the ZnO layer. The chemistry may be made selective to ZnO so that the top silicon layer is not eroded. The structure appears as in FIG. 9.

The remaining steps are performed in order to make electrical contact to the two terminals of the device: layer 20 and layer 22. A coating of insulating material 42, such as SiO₂ or Si₃N₄, etc., is deposited 44, patterned 46, filled 48 with metal 50, and then patterned again to arrive at the structure in FIG. 10. In addition to serving as electrical insulation, insulating material 42 may be selected to serve as a selective diffusion barrier to increase the selective sensitivity of the device to various gases.

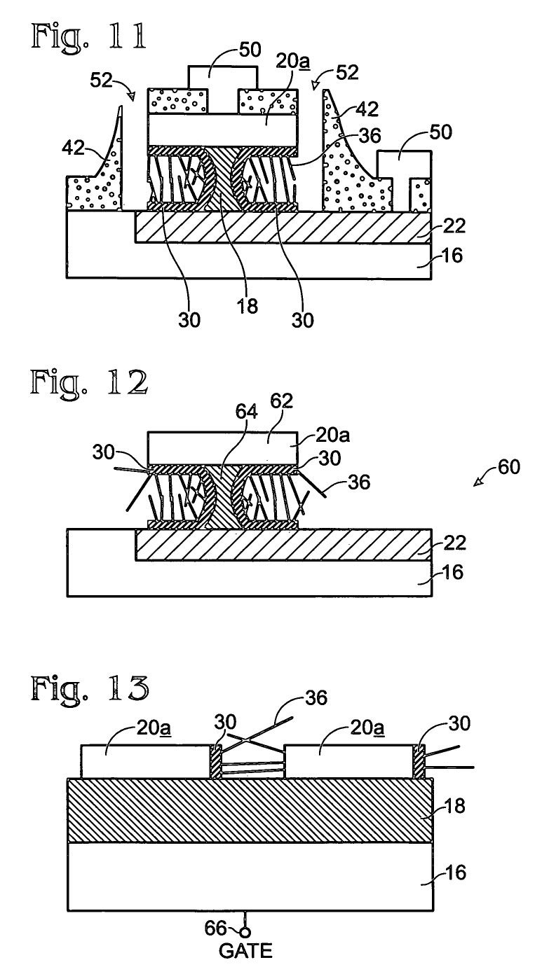

An alternative embodiment is shown in FIG. 11, wherein a hole 52 is dry etched 54 down to the sensitive area so that gases may proceed to the device unimpeded.

A device constructed according to the method of the invention will work similarly to previously described planar devices in that exposure to gases will modify the surface of the ZnO so as to change the conductivity of the wires, which is measured between the two terminals. Changes in conductivity may be empirically tied to changes in gas concentration. Because of the increased surface area, any device constructed according to the method of the invention is much more sensitive than a planar device.

The other standard components of such gas sensors such as a resistive heater, temperature sensor, etc., may be fabricated around this device by standard IC fabrication methods which are well known in the industry. It is likely that the method of the invention will be functional and have utility when using other appropriate seed layers for other nanowire structures, such as ALD In₂O₃ for In₂O₃ nanowires, etc.

In another variation of the method of the invention, a structure 60, shown in FIG. 12, may be fabricated using polysilicon 62 on oxide 64 on a silicon substrate 16. An advantage to this variation of the method of the invention is that the implanted well in the substrate may be formed before the oxide is deposited.

Another alternative embodiment is shown in FIG. 13. Rather than etching completely through buried oxide layer 22 (step 26), the etch is terminated once top silicon layer 20 is cleared, thus eliminating step 26 of FIG. 1 from this embodiment of the method of the invention. ALD ZnO film 30 is deposited, patterned and etched, selectively removing ZnO, leaving a sidewall layer that acts as a seed layer for nanostructure growth on only one side of silicon islands 20a. The two silicon islands are bridged only by the nanostructures, which extend, as shown in FIG. 13, from the ZnO seed layer on one silicon island to the spaced apart single crystalline silicon of another, adjacent, spaced apart, silicon island. A ZnO seed layer may also be provided on both spaced-apart silicon island, and the resultant nanowires will extend from the ZnO seed layer on one silicon island to the ZnO seed layer on the other silicon island. The structure of FIG. 13 has the added advantage of removing the ALD film between the two electrical terminals to confine the current flow through the nanostructures and avoid any current flow through the ALD layer, which may be substantial compared to the signal being detected. Another advantage to the structure of this embodiment of the method of the invention is that a back gate 66 may be fabricated, allowing operation of a device constructed according to the method of the invention in a MOS transistor mode, which is not feasible using the previously described embodiments, which provides a means for tuning the sensitivity and response time of a sensor.

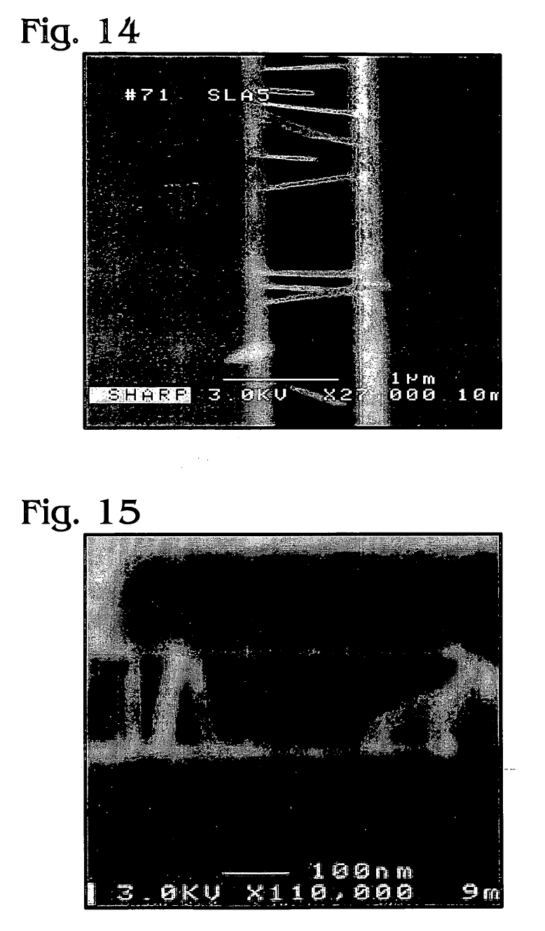

FIGS. 14 and 15 depict SEM photos of nanowire structures fabricated according to the method of the invention. FIG. 14 depicts a top view of an alternate embodiment of a structure fabricated according to the alternate embodiment of the method of the invention, while FIG. 15 depicts a cross-section of a structure fabricated according to the principal method of the invention. The SEM photos clearly demonstrate the utility of the method of the invention for fabricating ZnO nanostructures.

Thus, a method for fabricating nanowire sensor device structures has been disclosed. It will be appreciated that further variations and modifications thereof may be made within the scope of the invention as defined in the appended claims.

We claim:

1. A method of fabricating a nanowire sensor device structure comprising:
preparing a substrate, having a silicon base layer, a buried oxide layer in the silicon base layer, a top silicon layer on the buried oxide layer, and a doped well in the silicon base layer;
forming a silicon island from the top silicon layer;
etching the buried oxide layer to undercut the silicon island;
depositing a seed layer of polycrystalline ZnO over the silicon island, the buried oxide layer, the doped well and the silicon base layer;
removing the polycrystalline ZnO from the top of the silicon island;
growing and structuring ZnO nanostructures on the seed layer of ZnO;
treating the ZnO nanostructures to sensitize the ZnO nanostructures to a desired application;
depositing a layer of insulating material;
patterning and etching the insulating material; and
metallizing the nanowire device structure.

2. The method of claim 1 wherein said depositing a seed layer of polycrystalline ZnO includes depositing between about 1 nm to 70 nm of ZnO by ALD to conformally coat the underside of the undercut silicon island with ZnO.

3. The method of claim 1 wherein the top silicon layer is formed of material taken from the group of materials consisting of single crystal silicon and polycrystalline silicon.

4. The method of claim I which further includes etching a hole in the insulating material to open the ZnO nanostructures.

5. A method of fabricating a nanowire sensor device structure comprising:
preparing a substrate, having a silicon base layer, a buried oxide layer in the silicon base layer, a top silicon layer on the buried oxide layer, and a doped well in the silicon base layer, wherein the top silicon layer is formed of material taken from the group of materials consisting of single crystal silicon and polycrystalline silicon;
forming a silicon island from the top silicon layer;
etching the buried oxide layer to undercut the silicon island;
depositing a seed layer of polycrystalline ZnO over the silicon island, the buried oxide layer, the doped well and the silicon base layer;
removing the polycrystalline ZnO from the top of the silicon island;
growing and structuring ZnO nanostructures on the seed layer of ZnO;
treating the ZnO nanostructures to sensitize the ZnO nanostructures to a desired application;
depositing a layer of insulating material;
patterning and etching the insulating material; and
metallizing the nanowire device structure.

6. The method of claim 5 wherein said depositing a seed layer of polycrystalline ZnO includes depositing between about 1 nm to 70 nm of ZnO by ALD to conformally coat the underside of the undercut silicon island with ZnO.

7. The method of claim 5 which further includes etching a hole in the insulating material to open the ZnO nanostructures.

8. A method of fabricating a nanowire sensor device structure comprising:
preparing a substrate, having a silicon base layer, a buried oxide layer in the silicon base layer, a top silicon layer on the buried oxide layer, and a doped well in the silicon base layer;
forming a silicon island from the top silicon layer;
depositing a seed layer of polycrystalline ZnO over the silicon island, the buried oxide layer, the doped well and the silicon base layer, to a thickness of between about 1 nm to 70 nm by ALD to conformally coat the silicon island with ZnO.;
removing the polycrystalline ZnO from the top of the silicon island;
growing and structuring ZnO nanostructures on the seed layer of ZnO;
treating the ZnO nanostructures to sensitize the ZnO nanostructures to a desired application;
depositing a layer of insulating material;
patterning and etching the insulating material; and
metallizing the nanowire device structure.

9. The method of claim 8 wherein the top silicon layer is formed of material taken from the group of materials consisting of single crystal silicon and polycrystalline silicon.

10. The method of claim 8 which further includes etching a hole in the insulating material to open the ZnO nanostructures.

11. The method of claim 8 which further includes fabricating a back gate to the nanowire sensor device.

12. The method of claim 8 wherein said removing the polycrystalline ZnO from the top of the silicon island includes removing polycrystalline ZnO from one edge of the silicon island.
